(19) United States
(12) Patent Application Publication
(10) Pub. No.: US 2026/0342333 A1
(43) Pub. Date: Oct. 29, 2026

(54) ISOLATED DRIVER CIRCUIT

(71) Applicant: NAVITAS SEMICONDUCTOR LIMITED, Dublin (IE)

(72) Inventors: Vincent DESSARD, Mont-saint-Guibert (BE); Aimad SAIB, Gembloux (BE); Stéphane ADRIAENSEN, Limelette (BE); Xavier BAIE, Gembloux (BE); Ju Jason ZHANG, Monterey Park, CA (US); Daniel M. KINZER, El Segundo, CA (US)

(73) Assignee: NAVITAS SEMICONDUCTOR LIMITED, Dublin (IE)

(21) Appl. No.: 19/653,870

(22) Filed: Apr. 21, 2026

Related U.S. Application Data
(60) Provisional application No. 63/793,594, filed on Apr. 23, 2025.

(51) Int. Cl. H03K 17/687; H02M 1/088

(52) U.S. Cl. CPC H03K 17/6871; H02M 1/088

(57) ABSTRACT

A circuit may include a first switch having a first gate terminal, a first source terminal, and a first drain terminal, and a second switch having a first terminal coupled to a supply node and a second terminal coupled to the first gate terminal, the second switch configured to source current to the first gate terminal. An impedance element may be coupled between a supply voltage terminal and the supply node and configured to limit a magnitude of current sourced through the second switch to the first gate terminal. A current flow control circuit may be configured to selectively activate the second switch to drive the first gate terminal. In some embodiments, the circuit further includes a regulator circuit configured to maintain a regulated voltage within an operating range during a dip in the supply voltage.

### CROSS REFERENCE TO RELATED APPLICATIONS

This application claims priority to US provisional patent application no. 63/793,594, for “Isolated Driver Circuit” filed on Apr. 23, 2025, which is hereby incorporated by reference in entirety for all purposes.

### FIELD

The described embodiments relate generally to power converters, and more particularly, the disclosure relates to isolated driver circuits used in power converters.

### BACKGROUND

Electronic devices such as computers, servers and televisions, among others, employ one or more electrical power conversion circuits to convert one form of electrical energy to another. Some electrical power conversion circuits convert a high (or low) DC voltage to a lower (or higher) DC voltage using a circuit topology called DC-DC converter. Gate driver circuits play an essential role in the efficient switching of power transistors, particularly in DC-DC converter topologies employing wide-bandgap semiconductor devices such as silicon carbide (SiC) and gallium nitride (GaN) transistors. As many electronic devices are sensitive to size and efficiency of the power conversion circuit, new power converters can provide relatively higher efficiency and lower size for the new electronic devices.

### SUMMARY

In some embodiments, a circuit is disclosed. The circuit may include a first switch having a first gate terminal, a first source terminal, and a first drain terminal; a second switch having a first terminal coupled to a supply node and a second terminal coupled to the first gate terminal, the second switch configured to source current to the first gate terminal; an impedance element coupled between a supply voltage terminal and the supply node, the impedance element configured to limit a magnitude of current sourced through the second switch to the first gate terminal; and a current flow control circuit configured to selectively activate the second switch to drive the first gate terminal.

In some embodiments, the impedance element includes a resistor, and where a resistance value of the resistor is selectable to adjust a pull-up strength of the circuit at the first gate terminal.

In some embodiments, the circuit further includes a regulator circuit configured to generate a regulated voltage and further configured to maintain the regulated voltage within an operating range during a dip in the supply voltage caused by current sourced through the impedance element.

In some embodiments, the regulator circuit includes a rectifier element coupled in series with a resistive element between the supply node and a regulated output node.

In some embodiments, the circuit further includes a plurality of pull-down switches coupled between the first gate terminal and a ground node, the plurality of pull-down switches configured to be selectively enabled by control logic to adjust a pull-down strength at the first gate terminal.

In some embodiments, a drive capability of each of the plurality of pull-down switches is different, and where the plurality of pull-down switches are programmable using an electronic fuse to set a predetermined pull-down strength.

In some embodiments, the resistance value of the resistor is programmable using an electronic fuse.

In some embodiments, a circuit is disclosed. The circuit includes a first switch having a first gate terminal, a first source terminal, and a first drain terminal; an impedance element having a first end configured to receive a supply voltage and a second end coupled to a supply node; a second switch having a first terminal coupled to the supply node and a second terminal coupled to the first gate terminal, the second switch configured to source current to the first gate terminal; and a current flow control circuit configured to selectively activate the second switch to drive the first gate terminal.

In some embodiments, the circuit further includes a regulator circuit configured to generate a regulated voltage, where the regulator circuit is configured to maintain the regulated voltage within an operating range during a dip in a supply voltage caused by current sourced through the impedance element.

In some embodiments, the impedance element includes a resistor, and where a resistance value of the resistor is selectable to adjust a pull-up strength of the circuit at the first gate terminal.

In some embodiments, the resistance value of the resistor is programmable using an electronic fuse.

In some embodiments, the circuit further includes a plurality of pull-down switches coupled between the first gate terminal and a ground node, the plurality of pull-down switches configured to be selectively enabled by control logic to adjust a pull-down strength at the first gate terminal.

In some embodiments, a drive capability of each of the plurality of pull-down switches is different, and where the plurality of pull-down switches are programmable using an electronic fuse to set a predetermined pull-down strength.

In some embodiments, the circuit further includes a third switch having a second gate terminal, a second source terminal, and a second drain terminal, where the first drain terminal is coupled to a supply rail, the second drain terminal is coupled to the first source terminal at an output node, the second source terminal is coupled to a ground node and where the first switch and the third switch forming a half-bridge configuration.

In some embodiments, a circuit is disclosed. The circuit includes a first switch having a first gate terminal, a first source terminal, and a first drain terminal; a plurality of pull-down switches coupled to the first gate terminal and configured to be selectively enabled to sink current from the first gate terminal to a ground node, the plurality of pull-down switches providing a pull-down strength sufficient to prevent an unwanted turn-on of the first switch caused by a Miller capacitance of the first switch without a dedicated Miller clamp pin, and a control logic circuit configured to receive an input signal and, in response, selectively enable one or more of the plurality of pull-down switches to drive the first gate terminal from a turn-on voltage to a turn-off voltage.

### BRIEF DESCRIPTION OF THE DRAWINGS

FIG. 1A illustrates a simplified schematic of an isolated driver circuit used for driving power switches, according to some embodiments;

FIG. 1B illustrates a simplified schematic of the isolated driver circuit used for driving GaN power switches, according to some embodiments. In some embodiments, the GaN power switches may be disposed on a GaN die that can include GaN-based circuits that, for example, can monitor operational parameters of the GaN power switches;

FIG. 1C illustrates a simplified schematic of the isolated driver circuit used for driving a bidirectional GaN power switch, according to some embodiments;

FIG. 2 illustrates a schematic of an isolated driver circuit with pull-up strength adjustment and pull-down strength adjustment, according to some embodiments;

FIG. 3A shows a regulator circuit that may be included in the driver circuit of FIG. 2, according to some embodiments. FIG. 3B shows a graph illustrating a dip in the Vcc value that may occur when an impedance element is placed at the input pin of an isolated driver circuit; and

FIG. 4 illustrates a schematic of an isolated driver circuit with adjustable pull-down strength element, according to some embodiments.

### DETAILED DESCRIPTION

Circuits and related techniques disclosed herein relate generally to power conversion devices. More specifically, devices, circuits and related techniques disclosed herein relate to isolated driver circuits that can be used for driving power devices including gallium nitride (GaN)-based, silicon carbide-based, IGBT and/or silicon-based power switches in various switched power and motor control applications. In some embodiments, the isolated driver may be in a semiconductor package with a reduced number of pins (compact package). In various embodiments, an isolated driver circuit may be arranged to drive GaN bidirectional power switches. In some embodiments, an isolated driver circuit may include isolation between a relatively low-voltage side and a relatively high-voltage side, and may be arranged to drive half-bridge circuits operating in relatively high-voltage domains.

In various embodiments, an isolated driver circuit may include three semiconductor dies, where a first semiconductor die may operate with respect to a first ground, and the second and third semiconductor dies may operate with respect to second and third grounds, respectively. In some embodiments, an isolation barrier, such as, but not limited to, a capacitive isolation may be present between the first die and the second and third dies. In various embodiments, a functional isolation may exist between the second and third dies.

In some embodiments, where the isolated driver circuit is used for driving a half-bridge, the isolated driver circuit may include a series connected resistor on the positive supply rail for adjusting pull-up strength. In various embodiments, the isolated driver circuit may include a series connected resistor on the output connecting to the gate of the power switch, where the series connected resistor can be used for adjusting pull-down strength. The pull-down strength of the isolated driver circuit can be customized internally by, for example, eFuse and/or an internal metal change. Various embodiments are described herein, including methods, processes, systems, devices, and the like.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

In some embodiments, the pull-up and pull-down drive strengths at the gate terminal of a power transistor may be adjusted by placing an external gate resistor in series between the driver output pin and the gate terminal of the power device. This external gate resistor may limit the peak gate current during switching transitions, thereby controlling the switching speed. The use of a single external gate resistor to control both the pull-up and pull-down drive strengths can be inflexible, as it may apply the same impedance to both the turn-on and turn-off transitions, which may have different optimal switching speed requirements. In various embodiments, to independently control the turn-on and turn-off switching speeds, an external gate diode may be placed in series with a separate pull-up or pull-down resistor, allowing asymmetric drive strength adjustment. In some embodiments, the use of an external gate diode may introduce additional system cost and board area, and may be incompatible with gate driver configurations that use a negative gate voltage during the off-state because the diode forward voltage drop and reverse blocking characteristics may interfere with the negative voltage clamping operation.

In certain embodiments, in a half-bridge gate driver integrated circuit housed in a compact package such as a small outline integrated circuit (SOIC) package, the number of available pins per isolated output channel may be limited. This pin constraint may eliminate the possibility of providing a dedicated external gate resistor pin for the pull-up path that is separate from the supply rail pin. In various embodiments, adjusting the pull-up drive strength in pin-constrained isolated gate driver packages may use external gate diode approach described above, which may be incompatible with Miller clamp operation employing negative gate voltages.

In some embodiments, Miller clamp circuits may be used in gate driver ICs to prevent parasitic turn-on of the power transistor caused by the Miller capacitance coupling a voltage transient from the drain terminal to the gate terminal during fast switching of the complementary transistor in a half-bridge configuration. The Miller clamp circuit can actively hold the gate terminal of the off-state transistor at or below the threshold voltage thereby preventing the gate voltage from rising sufficiently to cause unintended conduction. In various embodiments, the effectiveness of the Miller clamp circuit may be related to the impedance of the pull-down path at the gate terminal; a lower pull-down impedance can provide stronger clamping and greater immunity to parasitic turn-on. In some embodiments, when an external gate diode is used to independently control the pull-up drive strength, the diode can be placed in the pull-up path, leaving the pull-down path and Miller clamp path unaffected. In various embodiments where the pull-down drive strength may be adjusted, an interaction between the external gate resistor, the Miller clamp circuit, and the gate diode may may degrade clamping performance.

In some embodiments, an alternative approach to adjusting pull-up drive strength without the use of an external gate diode may involves placing a series impedance element, such as a resistor, on the positive supply rail of the gate driver rather than in the gate output path. By limiting the current available to the pull-up switch through the supply rail impedance, the effective pull-up drive strength at the gate terminal can be controlled. This approach may introduce a localized voltage dip on the supply rail during each gate pull-up current transient, as the voltage drop across the series impedance element may reduce the effective supply voltage available to the internal circuitry of the gate driver during the switching event.

In some embodiments, pull-down drive strength adjustment external gate resistors may be used to set the pull-down current capability. This approach can employ the use of additional passive components on the printed circuit board, which may increase system cost and board area. In various embodiments, in applications where the gate driver integrated circuit is used in applications with multiple end-use configurations with different optimal pull-down drive strengths, the use of a fixed external gate resistor may increase design complexity and the risk of incorrect configuration. In some embodiments, internal switches of different sizes that can be selectively enabled have been combined with a Miller clamp architecture in which the pull-down path itself provides the Miller clamping function, thereby eliminating use of a dedicated Miller clamp output pin and further reducing pin count requirements.

In various embodiments, in isolated half-bridge gate driver circuits, the startup behavior of the high-side and low-side channels may be different. The high-side channel supply voltage may be generated by a bootstrap circuit, which charges a bootstrap capacitor during the on-time of the low-side transistor. As a result, the high-side supply voltage may rise progressively from zero at system startup and can be dependent upon the switching history of the half-bridge. In contrast, the low-side channel supply voltage may be derived directly from a regulated supply and can be promptly available upon power-up. In some embodiments, gate driver circuits can distinguish between these two startup conditions in their initialization and startup sequencing logic, and can prevent potentially undefined or uncontrolled gate drive behavior during the startup transient.

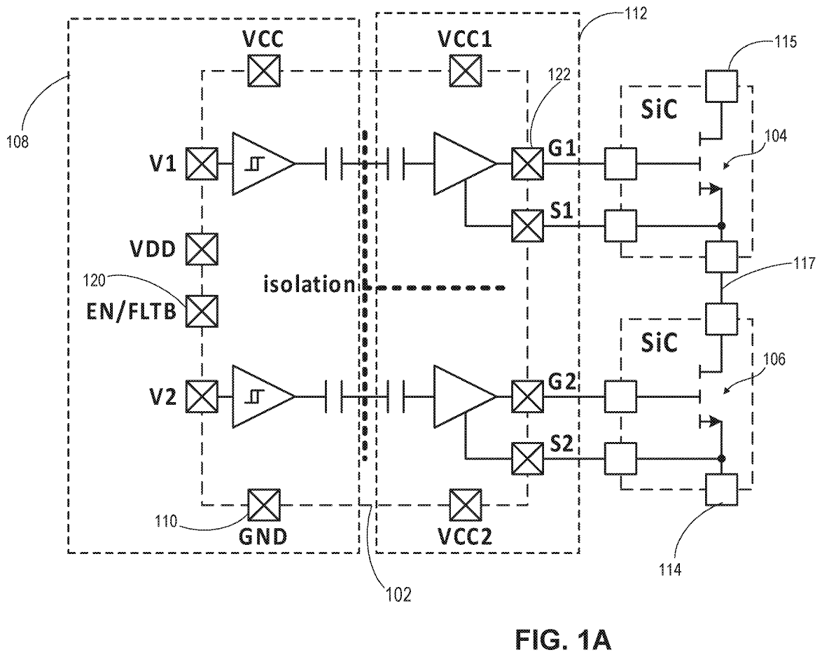

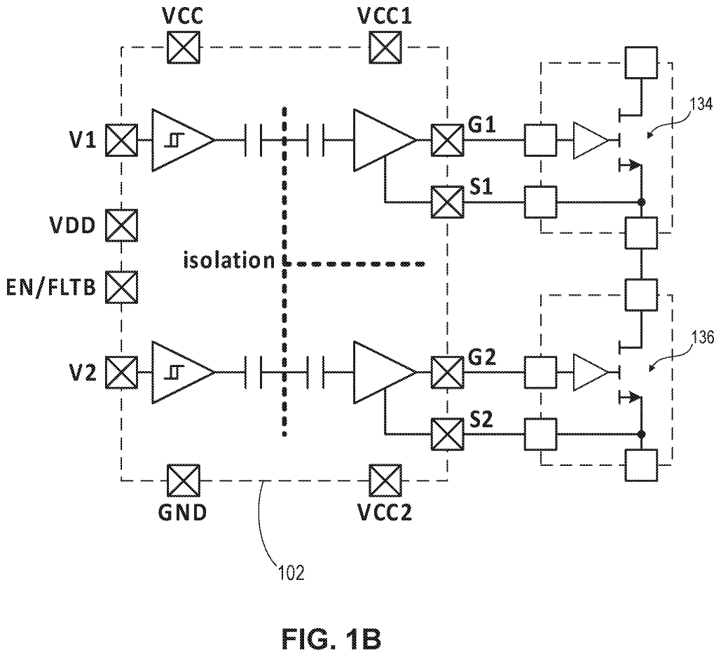

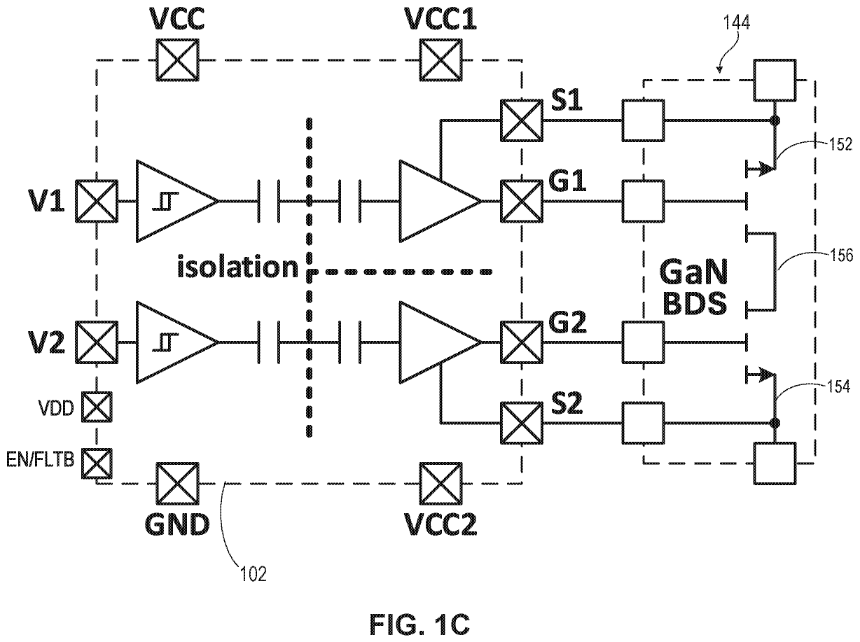

FIG. 1A illustrates a simplified schematic of an isolated driver circuit used for driving power switches, according to some embodiments. FIG. 1A shows a driver circuit 102 coupled to a first silicon carbide switch 104 and a second silicon carbide switch 106. The driver circuit 102 can include a primary side 108 that is referenced to ground node 110 (GND) and may operate in a relatively low voltage domain. The first silicon carbide switch 104 can be connected to the second silicon carbide switch 106 at a switch node 117. The first silicon carbide switch 104 may be connected between an input terminal 115 and the switch node 117. The driver circuit 102 can include a secondary side 112 that is referenced to ground node 114 and may operate in a relatively high voltage domain. The primary side 108 can be isolated from the secondary side 112 by, for example, capacitive isolation. The driver circuit 102 can include a first semiconductor die in the primary side, and a second and third semiconductor dies included in the secondary side. The first, second and third semiconductor dies can be co-packaged in a unitary semiconductor package. The first, second and third semiconductor dies can be connected via bondwires or clips or the like.

The first semiconductor die may include control circuits arranged to receive input signals and transmit control signals to the second and third semiconductor dies. The second semiconductor die can include high-side driver circuits that can be arranged to receive isolated control signals and provide drive signals to gate terminal of the silicon carbide switch 104. The third semiconductor die can include low-side driver circuits that can be arranged to receive isolated control signals and provide drive signals to gate terminal of the silicon carbide switch 106. The second and third semiconductor dies can be functionally isolated. In some embodiments, an isolation voltage between an input pin 120 to an output pin 122 can be, for example, 6000 V.

FIG. 1B illustrates a simplified schematic of the isolated driver circuit 102 used for driving GaN-based power switches, according to some embodiments. FIG. 1B shows the driver circuit 102 coupled to a first GaN switch 134 and a second GaN switch 136. The GaN switches 134 and 136 can be discrete, or can be integrated in a unitary GaN die. In some embodiments, the unitary GaN die may include GaN-based circuits that, for example, can monitor operational parameters of the first and second GaN-based power switches and transmit the operational parameters, such as, but not limited to, operating temperature, to the isolated driver circuit.

FIG. 1C illustrates a simplified schematic of the isolated driver circuit 102 used for driving a bidirectional GaN power switch, according to some embodiments. FIG. 1C shows the driver circuit 102 coupled to a bidirectional GaN switch 144. The bidirectional GaN switch 144 can be disposed on a GaN die. The bidirectional GaN switch 144 may be formed on a GaN-based substrate and include a first source node 152, a second source node 154 and a common drain node 156.

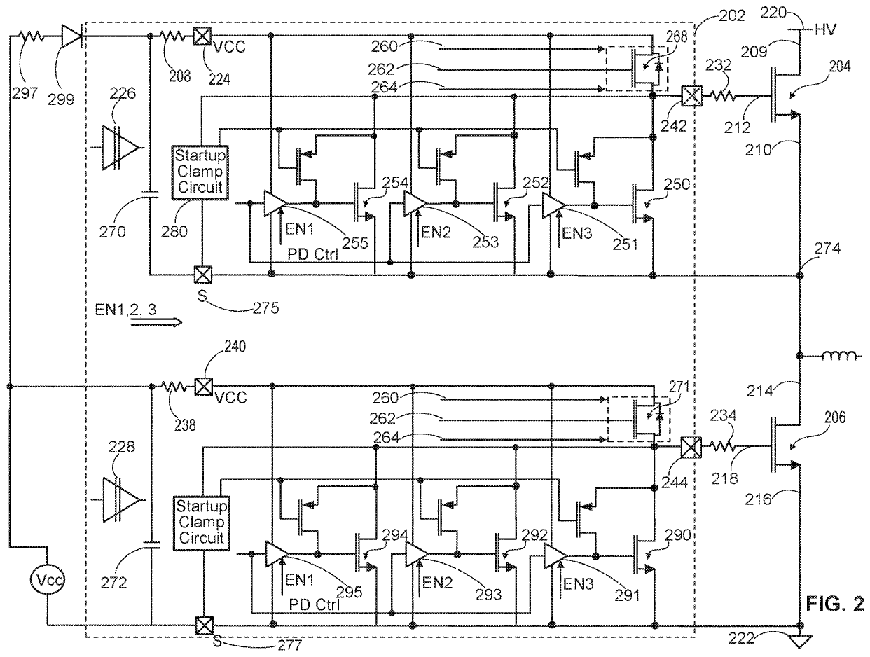

FIG. 2 illustrates a schematic of an isolated driver circuit with pull-up strength adjustment and pull-down strength adjustment, according to some embodiments. FIG. 2 shows a driver circuit 202 connected to a first power switch 204 and a second power switch 206. The power switch 204 can have a drain terminal 209, a source terminal 210 and a gate terminal 212. The power switch 206 can have a drain terminal 214, a source terminal 216 and a gate terminal 218. The source terminal 210 can be connected to drain terminal 214 at a switch node 274. The switch node 274 may be connected to a first low potential pin 275. The drain terminal 209 can be connected to a relatively high-voltage input terminal 220. The source terminal 216 can be connected to ground 222. The ground 222 may be connected to a second low potential pin 275. The driver circuit 202 can include an isolation barrier 226 for the high-side circuits and an isolation barrier 228 for the low-side circuits.

An impedance element 208 can be connected to an input pin 224. An impedance element 238 can be connected to an input pin 240. An impedance element 232 can be connected between an output pin 242 and the gate terminal 212. An impedance element 234 can be connected between an output pin 244 and the gate terminal 218. In some embodiments, the impedance elements can be a resistor. The impedance element 208 can be arranged to adjust a pull-up strength of the driver circuit 202. In current approaches, a first resistor in parallel with a serially connected diode with a second resistor may be placed at a gate terminal of a power switch. In current approaches, the diode voltage-drop as well as the miller capacitance to the diode may create performance issues. In current approaches, the resistor at the gate terminal is used during turn-on of the power switch, while the serially connected diode/resistor are used during turn-off of the power switch. In some embodiments, a pull-up strength adjustment impedance element may be connected to the input VCC pin, while only a pull-down strength adjustment impedance element may be placed at the gate terminal of the power switch. In this way, the pull-up strength of the driver circuit 202 can be adjusted by changing a value of the impedance element 208 and/or 238. By placing the pull-up strength adjustment impedance element(s) at the VCC pin, the capacitive discharge of the power switch during turn-off is not affected. Further, by placing a pull-down impedance element at the gate terminal of the power switch, capacitive discharge speed of the power switch can be adjusted.

The driver circuit 202 can include high-side circuits that can have pull-down switches 250, 252 and 254 connected to the output pin 242. The output pin 242 can be connected to the gate terminal 212 through the pull-down impedance element 232. The pull-down switches 250, 252 and 254 may be controlled by circuits 251, 253 and 255, respectively. In various embodiments, circuits 251, 253 and 255 can be analog drive circuits and/or logic drive circuit.

In some embodiments, the pull-down switches 250, 252 and 254 can be arranged to change a voltage at a gate terminal 212 from an on voltage to an off voltage, such that the voltage at the gate terminal is changed at a first rate of voltage with respect to time from the on voltage to a first intermediate voltage, and at a second rate of voltage with respect to time from the first intermediate voltage to a second intermediate voltage, where the first rate is faster than the second rate. The pull-down switches 250, 252 and 254 can further be arranged to change the voltage at the gate terminal at a third rate of voltage with respect to time from the second intermediate voltage to an off voltage. The third rate can be faster than the second rate. In various embodiments, pull-down switch 254 may have a drive capability of, for example, 1 A, pull-down switch 252 may have a drive capability of, for example, 2 A, and pull-down switch 250 may have a drive capability of, for example, 4 A.

The driver circuit 202 can include a pull-up switch 268 connected to the output pin 242. The driver circuit 202 can also include a pull-up switch 271 connected to the output pin 244. In some embodiments, the pull-up switch 268 can be an NMOSFET. In various embodiments, the pull-up switch 268 can be a PMOSFET. In some embodiments, the pull-up switch 268 can include both NMOSFETs and PMOSFETs. In some embodiments, the pull-up switch 271 can be an NMOSFET. In various embodiments, the pull-up switch 271 can be a PMOSFET. In some embodiments, the pull-up switch 271 can include both NMOSFETs and PMOSFETs. A current flow control circuit may provide signals at node 260, 262 and 264. The pull-up switches 268 and 271 can be arranged to be controlled by the signal at node 260 being a pull-up control signal, the signal at node 262 being a pull-up strength signal, and the signal at node 264 being a pull-up clamp level signal. In some embodiments, each of the pull-up switches 268 and 271 can be separately controlled by separate signals. The driver circuit 202 can include a bootstrap capacitor 270 connected between the switch node 274 and the impedance element 208. In some embodiments where the isolated driver circuit is used for driving silicon carbide-based switches, the bootstrap capacitor 270 may be connected between a kelvin sense pin of the first switch 204 and the impedance element 208.

The driver circuit 202 can include low-side circuits that can have pull-down switches 290, 292 and 294 connected to the output pin 244. The output pin 244 can be connected to the gate terminal 218 through the pull-down impedance element 234. The pull-down switches 290, 292 and 294 may be controlled by circuits 291, 293 and 295, respectively. In various embodiments, circuits 291, 293 and 295 can be analog driver circuits and/or logic drive circuit.

In some embodiments, the pull-down switches 290, 292 and 294 can be arranged to change a voltage at a gate terminal 218 from an on voltage to an off voltage, such that the voltage at the gate terminal is changed at a first rate of voltage with respect to time from the on voltage to a first intermediate voltage, and at a second rate of voltage with respect to time from the first intermediate voltage to a second intermediate voltage, where the first rate is faster than the second rate. The pull-down switches 290, 292 and 294 can further be arranged to change the voltage at the gate terminal at a third rate of voltage with respect to time from the second intermediate voltage to an off voltage. The third rate can be faster than the second rate. In various embodiments, pull-down switch 294 may have a drive capability of, for example, 1 A, pull-down switch 292 may have a drive capability of, for example, 2 A, and pull-down switch 290 may have a drive capability of, for example, 4 A.

A bootstrap diode 299 in series with a bootstrap resistor 297 can be connected to the impedance element 208. The bootstrap diode 299, the bootstrap resistor 297, and the bootstrap capacitor 270 can be arranged to provide for bootstrapping functions of the circuit. The driver circuit 202 can further include a decoupling capacitor 272 connected between the ground 222 and the impedance element 238. The driver circuit 202 can also include a start-up clamp circuit 280. The decoupling capacitor can be arranged to reduce the oscillations during transients. In some embodiments, the impedance element 208 can be a resistor.

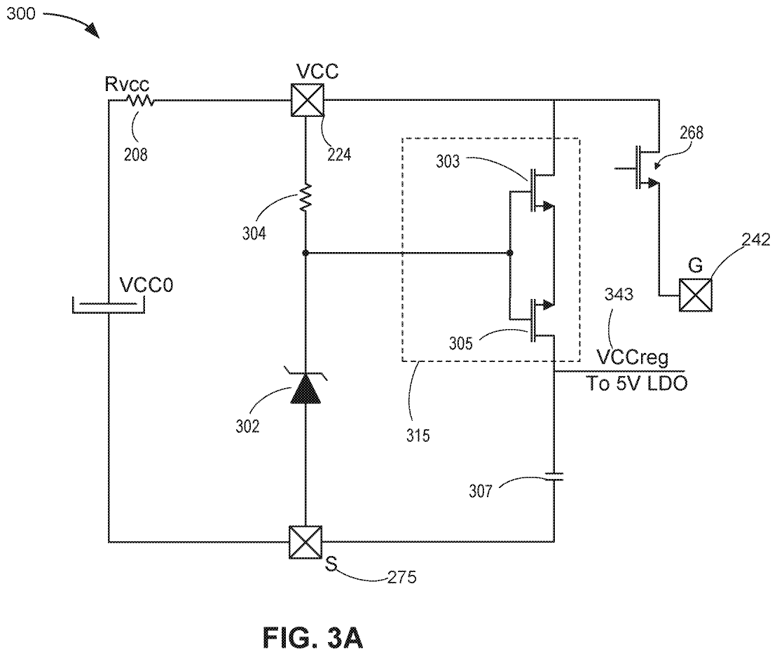

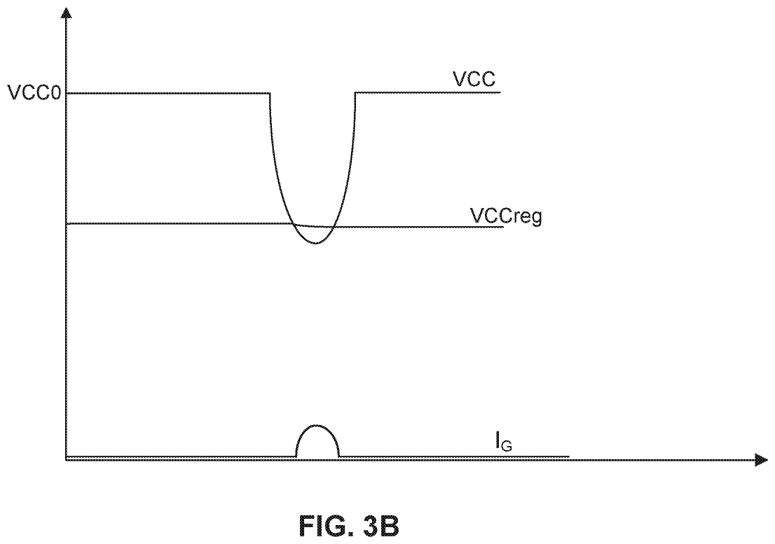

FIG. 3A shows regulator circuit 300 that may be included in the driver circuit 202, according to some embodiments. In some embodiments, having a pull-up impedance element at the positive supply rail may create a relatively brief dip in the local Vcc value. The regulator circuit 300 can be arranged to generate an internal Vcc voltage and keep the internal Vcc voltage from dipping below a predefined threshold. In FIG. 3A, a regulator circuit 300 can include a Zener diode 302 connected in series with a resistor 304. The resistor 304 may be connected to the input pin 224 and the Zener diode 302 may be connected to the first low potential pin 275.

The resistor 304 may also be connected to an output buffer circuit 315 that includes transistors 303 and 305. Transistor 305 may be connected to a capacitor 307. The buffer circuit 315 can be arranged to generate an output voltage 343 (labeled Vccreg).

FIG. 3B shows various voltage and currents of the circuit of FIG. 3A, according to some embodiments. The regulator circuit 300 can be arranged to prevent Vcc from dropping below the regulated voltage VCCreg. In this way, the high-side circuits can continue functioning during the turn-on of the driver circuit 202. In some embodiments, a dip in the Vcc value may occur when an impedance element is placed at the input pin 224. In various embodiments, the regulator circuit 300 can prevent that dip in Vcc value from affecting the regulated VCCreg. FIG. 3B also shows a relatively small increase in the gate current IG during the time period where the dip in Vcc may be present.

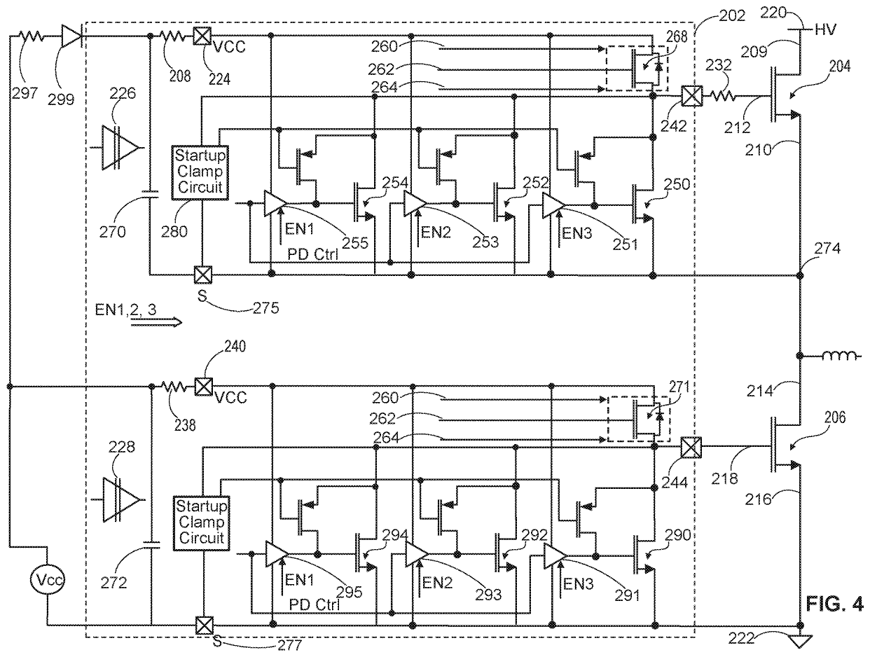

FIG. 4 illustrates a schematic of an isolated driver circuit with pull-down strength adjustment, according to some embodiments. The circuit in FIG. 4 is similar to FIG. 2, except impedance elements 232/234 have been removed. In some embodiments, when pull-down strength is adjusted appropriately for a given application using the enable EN1/2/3 logic to enable/disable the pull-down switches 250, 252 and 254, a value of the impedance element 232/234 can be substantially reduced, or reduced to zero, such that there is no impedance element connected at the gate terminal of the power switch. Further, an electronic fuse (eFuse) can be used to adjust a value of the pull-down strength in order to customize the driver for specific applications. In some embodiments, when the pull-down strength is sufficiently reduced by eFuse for a specific application, an external gate resistor 232/234 may not be used. In this way, the output gate voltage 242/244 may be relatively low due to the selected pull-down strength, and all pull-down transistors 250/252/254 can be turned-on together to provide a low clamping impedance (Miller Clamp). When the resistors 232/234 are equal to zero and the eFuse is appropriately set, the pull-down pad can act like a Miller Clamp (MC) pad. In this way, the miller capacitance can be managed without adding an extra pin to the package.

In some embodiments, combination of the circuits and methods disclosed herein can be utilized in an isolated driver circuit with reduced pin count. Although circuits and methods are described and illustrated herein with respect to several particular configuration of controlling power switches in half-bridge arrangements, embodiments of the disclosure are suitable for driving single and/or multiple switches in other arrangements, such as, but not limited to, full-bridge arrangements.

In the foregoing specification, embodiments of the disclosure have been described with reference to numerous specific details that can vary from implementation to implementation. The specification and drawings are, accordingly, to be regarded in an illustrative rather than a restrictive sense. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used.

Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A circuit comprising:
a first switch having a first gate terminal, a first source terminal, and a first drain terminal;
a second switch having a first terminal coupled to a supply node and a second terminal coupled to the first gate terminal, the second switch configured to source current to the first gate terminal;
an impedance element coupled between a supply voltage terminal and the supply node, the impedance element configured to limit a magnitude of current sourced through the second switch to the first gate terminal; and
a current flow control circuit configured to selectively activate the second switch to drive the first gate terminal.

2. The circuit of claim 1, wherein the impedance element comprises a resistor, and wherein a resistance value of the resistor is selectable to adjust a pull-up strength of the circuit at the first gate terminal.

3. The circuit of claim 1, further comprising a regulator circuit configured to generate a regulated voltage and further configured to maintain the regulated voltage within an operating range during a dip in a supply voltage caused by current sourced through the impedance element.

4. The circuit of claim 3, wherein the regulator circuit comprises a rectifier element coupled in series with a resistive element between the supply node and a regulated output node.

5. The circuit of claim 1, further comprising a plurality of pull-down switches coupled between the first gate terminal and a ground node, the plurality of pull-down switches configured to be selectively enabled by control logic to adjust a pull-down strength at the first gate terminal.

6. The circuit of claim 5, wherein a drive capability of each of the plurality of pull-down switches is different, and wherein the plurality of pull-down switches are programmable using an electronic fuse to set a predetermined pull-down strength.

7. The circuit of claim 2, wherein the resistance value of the resistor is programmable using an electronic fuse.

8. A circuit comprising:
a first switch having a first gate terminal, a first source terminal, and a first drain terminal;
an impedance element having a first end configured to receive a supply voltage and a second end coupled to a supply node;
a second switch having a first terminal coupled to the supply node and a second terminal coupled to the first gate terminal, the second switch configured to source current to the first gate terminal; and
a current flow control circuit configured to selectively activate the second switch to drive the first gate terminal.

9. The circuit of claim 8, further comprising a regulator circuit configured to generate a regulated voltage, wherein the regulator circuit is configured to maintain the regulated voltage within an operating range during a dip in a supply voltage caused by current sourced through the impedance element.

10. The circuit of claim 8, wherein the impedance element comprises a resistor, and wherein a resistance value of the resistor is selectable to adjust a pull-up strength of the circuit at the first gate terminal.

11. The circuit of claim 10, wherein the resistance value of the resistor is programmable using an electronic fuse.

12. The circuit of claim 8, further comprising a plurality of pull-down switches coupled between the first gate terminal and a ground node, the plurality of pull-down switches configured to be selectively enabled by control logic to adjust a pull-down strength at the first gate terminal.

13. The circuit of claim 12, wherein a drive capability of each of the plurality of pull-down switches is different, and wherein the plurality of pull-down switches are programmable using an electronic fuse to set a predetermined pull-down strength.

14. The circuit of claim 8, further comprising a third switch having a second gate terminal, a second source terminal, and a second drain terminal, wherein the first drain terminal is coupled to a supply rail, the second drain terminal is coupled to the first source terminal at an output node, the second source terminal is coupled to a ground node and wherein the first switch and the third switch form a half-bridge configuration.

15. A circuit comprising:
a first switch having a first gate terminal, a first source terminal, and a first drain terminal;
a plurality of pull-down switches coupled to the first gate terminal and configured to be selectively enabled to sink current from the first gate terminal to a ground node, the plurality of pull-down switches providing a pull-down strength sufficient to prevent an unwanted turn-on of the first switch caused by a Miller capacitance of the first switch without a dedicated Miller clamp pin; and
a control logic circuit configured to receive an input signal and, in response, selectively enable one or more of the plurality of pull-down switches to drive the first gate terminal from a turn-on voltage to a turn-off voltage.

16. The circuit of claim 15, wherein a drive capability of each of the plurality of pull-down switches is different, and wherein the plurality of pull-down switches are programmable using an electronic fuse to set a predetermined pull-down strength.

17. The circuit of claim 15, further comprising a second switch having a second gate terminal, a second source terminal, and a second drain terminal, wherein the first drain terminal is coupled to the second source terminal at a switch node, wherein the second drain terminal is coupled to an input terminal, the first switch and the second switch form a half-bridge configuration.

18. The circuit of claim 15, wherein the plurality of pull-down switches are coupled directly to the first gate terminal such that a pull-down impedance between the plurality of pull-down switches and the first gate terminal is substantially zero.

19. The circuit of claim 17, wherein the ground node is a second ground node, wherein the control logic circuit is configured to operate with respect to a first ground, wherein the first switch is configured to operate with respect to the second ground node, and wherein the second switch is configured to operate with respect to a third ground node, 20. The circuit of claim 17, wherein each of the plurality of pull-down switches is coupled to a respective analog driver circuit.
